(19) United States
(12) Patent Application Publication
(10) Pub. No.: US 2017/0148525 A1
(43) Pub. Date: May 25, 2017

(54) Method and System For Adaptively Adjusting a Verify Voltage to Reduce Storage Raw Bit Error Rate

(71) Applicant: SanDisk Technologies LLC, Plano, TX (US)

(72) Inventors: Gulzar Ahmed Kathawala, Fremont, CA (US); Yuan Zhang, Santa Clara, CA (US); Wenzhou Chen, Cupertino, CA (US); Sheunghee Park, Pleasanton, CA (US)

(21) Appl. No.: 15/186,339

(22) Filed: Jun. 17, 2016

Related U.S. Application Data
(60) Provisional application No. 62/260,210, filed on Nov. 25, 2015.

(51) Int. Cl. G11C 16/34; G11C 16/10; G06F 11/07

(52) U.S. Cl. CPC G11C 16/3459; G06F 11/0727; G06F 11/076; G06F 11/079; G06F 11/0793; G11C 16/10

(57) ABSTRACT

The various implementations described herein include systems, methods and/or devices used to enable adaptive verify voltage adjustment in memory devices. The method includes: (1) in conjunction with decoding data read from non-volatile memory in the non-volatile memory system, determining a plurality of error parameters, (2) determining, in accordance with the plurality of error parameters, a verify adjustment signal, (3) determining whether a verify trigger event has occurred, (4) in accordance with a determination that a verify trigger event has occurred, adjusting a verify voltage in accordance with the verify adjustment signal, and (5) performing data write operations to write data to non-volatile memory in the non-volatile memory system using the adjusted verify voltage to verify the data written using the data write operations.

### RELATED APPLICATIONS

This application claims priority to U.S. Provisional Patent Application No. 62/260,210, filed Nov. 25, 2015, which is hereby incorporated by reference in its entirety.

### TECHNICAL FIELD

The disclosed embodiments relate generally to memory systems, and in particular, to adaptive verify voltage adjustment in a non-volatile memory system (e.g., comprising one or more flash memory devices).

### BACKGROUND

Semiconductor memory devices, including flash memory, typically utilize memory cells to store data as an electrical value, such as an electrical charge or voltage. A flash memory cell, for example, includes a single transistor with a floating gate that is used to store a charge representative of a data value. Flash memory is a non-volatile data storage device that can be electrically erased and reprogrammed. More generally, non-volatile memory (e.g., flash memory, as well as other types of non-volatile memory implemented using any of a variety of technologies) retains stored information even when not powered, as opposed to volatile memory, which requires power to maintain the stored information.

Writing data to some types of non-volatile memory, including flash memory, may require verifying that the data was properly written. Verify voltages corresponding to the data values are used to perform the verification. However, errors in the data can occur between the time that the data is written to the memory and the time a read operation is performed to read the data in the memory cell. Therefore, it would be desirable to adaptively adjust the verify voltage for one or more portions of the memory to reduce the incidence of error.

### SUMMARY

Various embodiments of systems, methods and devices within the scope of the appended claims each have several aspects, no single one of which is solely responsible for the attributes described herein. Without limiting the scope of the appended claims, after considering this disclosure, and particularly after considering the section entitled “Detailed Description,” one will understand how the aspects of various embodiments are used to enable adaptive verify voltage adjustment in memory devices.

The disclosed device and method improve the endurance of non-volatile memory, such as flash memory, by adaptively adjusting a verify voltage to reduce storage raw bit error rate. In conjunction with decoding data read from non-volatile memory, a plurality of error parameters are determined, in accordance with which a verify adjustment signal is determined. Further, in accordance with a determination that a verify trigger event has occurred, and in accordance with the verify adjustment signal, a verify voltage is adjusted. Thereafter, data write operations are performed using the adjusted verify voltage.

### BRIEF DESCRIPTION OF THE DRAWINGS

So that the present disclosure can be understood in greater detail, a more particular description may be had by reference to the features of various embodiments, some of which are illustrated in the appended drawings. The appended drawings, however, merely illustrate the more pertinent features of the present disclosure and are therefore not to be considered limiting, for the description may admit to other effective features.

FIG. 1 is a block diagram illustrating an implementation of a non-volatile memory system, in accordance with some embodiments.

FIG. 2 is a block diagram illustrating a memory management module of a non-volatile memory controller, in accordance with some embodiments.

FIG. 3A is a prophetic diagram of voltage distributions that may be found in a single-level flash memory cell (SLC) over time, in accordance with some embodiments.

FIG. 3B is a prophetic diagram of voltage distributions that may be found in a multi-level flash memory cell (MLC) over time, in accordance with some embodiments.

FIG. 4A is a conceptual diagram showing adjustment of a verify voltage in a non-volatile memory system, in accordance with some embodiments.

FIG. 4B is a conceptual diagram of the effect of verify voltage adjustment on voltage distributions that may be found in an MLC over time, in accordance with some embodiments.

FIG. 4C is a conceptual diagram of error parameters derived from an error control module in a non-volatile memory system, in accordance with some embodiments.

FIG. 5 illustrates a conceptual flowchart representation of a method of adjusting a verify voltage in a non-volatile memory system, in accordance with some embodiments.

FIGS. 6A-6C illustrate a flowchart representation of a method of adjusting a verify voltage in a non-volatile memory system, in accordance with some embodiments.

In accordance with common practice the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

The various implementations described herein include systems, methods and/or devices used to enable adaptive verify voltage adjustment in memory devices. Some implementations include systems, methods and/or devices to adaptively adjust a verify voltage to reduce storage raw bit error rate.

(A1) More specifically, some embodiments include a method of operation in a non-volatile memory system. The method includes: (1) in conjunction with decoding data read from non-volatile memory in the non-volatile memory system, determining a plurality of error parameters, (2) determining, in accordance with the plurality of error parameters, a verify adjustment signal, (3) determining whether a verify trigger event has occurred, (4) in accordance with a determination that a verify trigger event has occurred, adjusting a verify voltage in accordance with the verify adjustment signal, and (5) performing data write operations to write data to non-volatile memory in the non-volatile memory system using the adjusted verify voltage to verify the data written using the data write operations.

(A2) In some embodiments of the method of A1, the plurality of error parameters are determined in accordance with data read operations performed at predefined usage milestones with respect to portions of the non-volatile memory in the non-volatile memory system.

(A3) In some embodiments of the method of any of A1-A2, determining the plurality of error parameters includes: (1) determining a first set of error counts for data read using a first set of voltage thresholds, (2) determining a second set of error counts for data read using a second set of voltage thresholds, and (3) computing a first set of one or more error parameters and a second set of one or more error parameters from the first and second sets of error counts.

(A4) In some embodiments of the method of A3, the first and second sets of error counts each include a plurality of error sum values.

(A5) In some embodiments of the method of A4, the first and second sets of error counts further include a plurality of error difference values.

(A6) In some embodiments of the method of any of A3-A5, determining, in accordance with the plurality of error parameters, the verify adjustment signal includes: (1) applying a first scaling factor to the second set of error parameters, (2) determining whether one or more parameters of the first set of error parameters exceeds one or more corresponding parameters of the scaled second set of error parameters, and (3) in accordance with a determination that the one or more parameters of the first set of error parameters exceeds the one or more corresponding parameters of the scaled second set of error parameters, setting the verify adjustment signal to a first adjustment value.

(A7) In some embodiments of the method of A6, determining, in accordance with the plurality of error parameters, the verify adjustment signal further includes: (1) applying a second scaling factor to the second set of error parameters, (2) determining whether one or more parameters of the scaled second set of error parameters exceeds one or more corresponding parameters of the first set of error parameters, and (3) in accordance with a determination that the one or more parameters of the scaled second set of error parameters exceeds the one or more corresponding parameters of the first set of error parameters, setting the verify adjustment signal to a second adjustment value.

(A8) In some embodiments of the method of any of A1-A7, determining whether the verify trigger event has occurred includes: (1) updating a status counter according to the verify adjustment signal, and (2) determining whether the status counter satisfies any respective range limit of a set of one or more range limits. In these embodiments, the method further includes, in accordance with a determination that the status counter satisfies a respective range limit of the set of one or more range limits, resetting the status counter to an initial value.

(A9) In some embodiments, the method of any of A1-A8 further includes repeating the method for each of a plurality of non-volatile memory portions to generate a separate adjusted verify voltage for each of the plurality of non-volatile memory portions.

(A10) In another aspect, a non-volatile memory system includes non-volatile memory, one or more processors, and memory storing one or more programs, which when executed by the one or more processors cause the non-volatile memory system to: (1) in conjunction with decoding data read from non-volatile memory in the non-volatile memory system, determine a plurality of error parameters, (2) determine, in accordance with the plurality of error parameters, a verify adjustment signal, (3) determine whether a verify trigger event has occurred, (4) in accordance with a determination that a verify trigger event has occurred, adjust a verify voltage in accordance with the verify adjustment signal, and (5) perform data write operations to write data to non-volatile memory in the non-volatile memory system using the adjusted verify voltage to verify the data written using the data write operations.

(A11) In some embodiments of the non-volatile memory system of A10, the one or more processors comprise one or more processors of a storage controller and the one or more programs include a verify voltage adjust module that determines the plurality of error parameters, determines the verify adjustment signal, determines whether the verify trigger event has occurred, and in accordance with a determination that a verify trigger event has occurred, adjusts the verify voltage in accordance with the verify adjustment signal.

(A12) In some embodiments of the non-volatile memory system of A10 or A11, the one or more programs include instructions that when executed by the one or more processors cause the non-volatile memory system to perform the method of any of A1-A9, described above.

(A13) In yet another aspect, a non-volatile memory system includes non-volatile memory, one or more processors, and memory storing one or more programs, which when executed by the one or more processors cause the non-volatile memory system to perform the method of any of A1-A9, described above.

(A14) In yet another aspect, a non-transitory computer readable storage medium stores one or more programs configured for execution by one or more processors of a non-volatile memory system, the one or more programs including instructions that when executed by the one or more processors cause the non-volatile memory system to perform the method of any of A1-A9, described above.

(A15) In yet another aspect, a non-volatile memory system includes: (1) means for determining, in conjunction with decoding data read from non-volatile memory in the non-volatile memory system, a plurality of error parameters, (2) means for determining, in accordance with the plurality of error parameters, a verify adjustment signal, (3) means for determining whether a verify trigger event has occurred, (4) means for adjusting, in accordance with a determination that a verify trigger event has occurred, a verify voltage in accordance with the verify adjustment signal, and (5) means for performing data write operations to write data to non-volatile memory in the non-volatile memory system using the adjusted verify voltage to verify the data written using the data write operations.

(A16) In yet another aspect, the non-volatile memory system of A15 is further configured to perform the method of any of A1-A9, described above.

Numerous details are described herein to provide a thorough understanding of the example implementations illustrated in the accompanying drawings. However, some embodiments may be practiced without many of the specific details, and the scope of the claims is only limited by those features and aspects specifically recited in the claims. Furthermore, well-known methods, components, and circuits have not been described in exhaustive detail so as not to unnecessarily obscure more pertinent aspects of the implementations described herein.

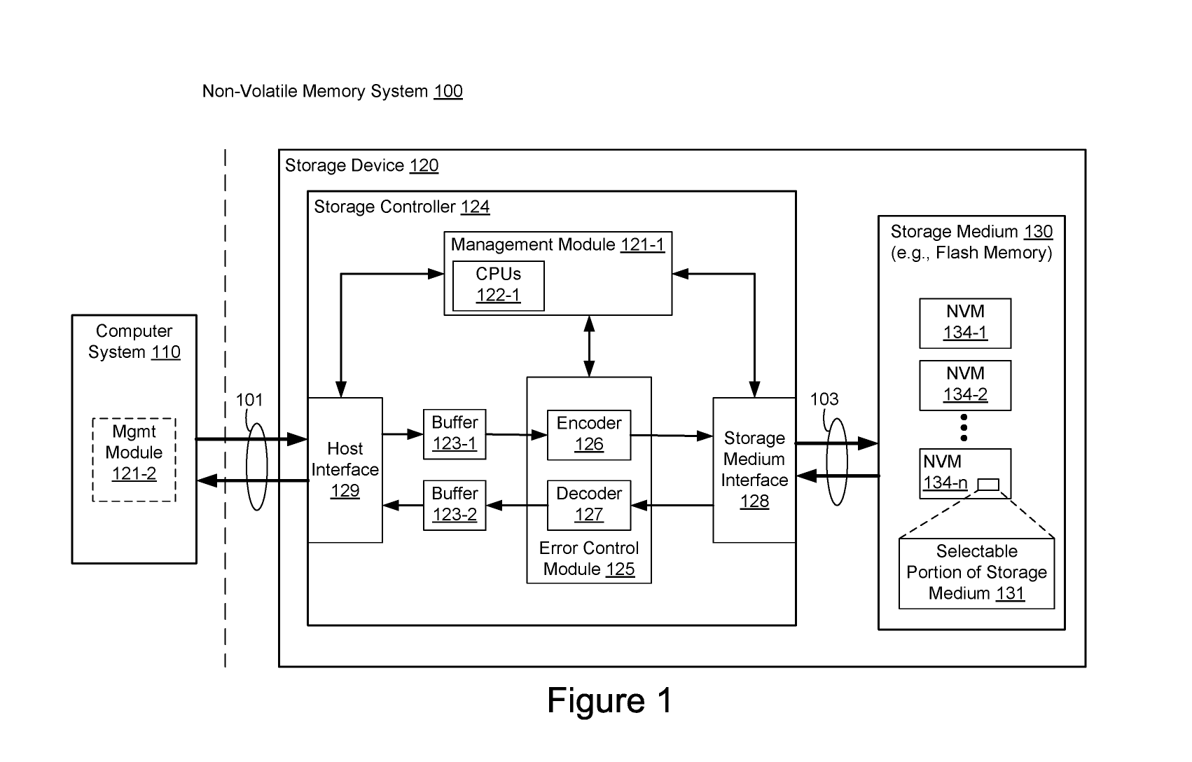

FIG. 1 is a block diagram illustrating an implementation of a non-volatile memory system 100, in accordance with some embodiments. While some example features are illustrated, various other features have not been illustrated for the sake of brevity and so as not to obscure pertinent aspects of the example embodiments disclosed herein. To that end, as a non-limiting example, non-volatile memory system 100 includes a storage device 120 (also sometimes called an information storage device, or a data storage device, or a memory device), which includes a storage controller 124 and a storage medium 130, and is used in conjunction with or includes a computer system 110 (e.g., a host system or a host computer). In some embodiments, storage medium 130 is a single flash memory device while in other embodiments storage medium 130 includes a plurality of flash memory devices. In some embodiments, storage medium 130 is NAND-type flash memory or NOR-type flash memory. In some embodiments, storage medium 130 includes one or more three-dimensional (3D) memory devices. Further, in some embodiments, storage controller 124 is a solid-state drive (SSD) controller. However, other types of storage media may be included in accordance with aspects of a wide variety of embodiments (e.g., PCRAM, ReRAM, STT-RAM, etc.). In some embodiments, a flash memory device includes one or more flash memory die, one or more flash memory packages, one or more flash memory channels or the like. In some embodiments, non-volatile memory system 100 (sometimes called a data storage system) includes one or more storage devices 120.

Computer system 110 is coupled to storage controller 124 through data connections 101. However, in some embodiments computer system 110 includes storage controller 124, or a portion of storage controller 124, as a component and/or as a subsystem. For example, in some embodiments, some or all of the functionality of storage controller 124 is implemented by software executed on computer system 110. Computer system 110 may be any suitable computer device, such as a computer, a laptop computer, a tablet device, a netbook, an internet kiosk, a personal digital assistant, a mobile phone, a smart phone, a gaming device, a computer server, or any other computing device. Computer system 110 is sometimes called a host, host system, client, or client system. In some embodiments, computer system 110 is a server system, such as a server system in a data center. In some embodiments, computer system 110 includes one or more processors, one or more types of memory, a display and/or other user interface components such as a keyboard, a touch-screen display, a mouse, a track-pad, a digital camera, and/or any number of supplemental I/O devices to add functionality to computer system 110. In some embodiments, computer system 110 does not have a display and other user interface components.

Storage medium 130 is coupled to storage controller 124 through connections 103. Connections 103 are sometimes called data connections, but typically convey commands in addition to data, and optionally convey metadata, error correction information and/or other information in addition to data values to be stored in storage medium 130 and data values read from storage medium 130. In some embodiments, however, storage controller 124 and storage medium 130 are included in the same device (i.e., an integrated device) as components thereof. Furthermore, in some embodiments, storage controller 124 and storage medium 130 are embedded in a host device (e.g., computer system 110), such as a mobile device, tablet, other computer or computer controlled device, and the methods described herein are performed, at least in part, by the embedded storage controller. Storage medium 130 may include any number (i.e., one or more) of memory devices (e.g., NVM 134-1, NVM 134-2 through NVM 134-n) including, without limitation, persistent memory or non-volatile semiconductor memory devices, such as flash memory device(s). For example, flash memory device(s) can be configured for enterprise storage suitable for applications such as cloud computing, for database applications, primary and/or secondary storage, or for caching data stored (or to be stored) in secondary storage, such as hard disk drives. Additionally and/or alternatively, flash memory device(s) can also be configured for relatively smaller-scale applications such as personal flash drives or hard-disk replacements for personal, laptop, and tablet computers.

Memory devices (e.g., NVM 134-1, NVM 134-2, etc.) of storage medium 130 include addressable and individually selectable blocks, such as selectable portion of storage medium 131 (also referred to herein as selected portion 131). In some embodiments, the individually selectable blocks (sometimes called erase blocks) are the minimum size erasable units in a flash memory device. In other words, each block contains the minimum number of memory cells that can be erased simultaneously. Each block is usually further divided into a plurality of pages and/or word lines, where each page or word line is typically an instance of the smallest individually accessible (readable) portion in a block. In some embodiments (e.g., using some types of flash memory), the smallest individually accessible unit of a data set, however, is a sector, which is a subunit of a page. That is, a block includes a plurality of pages, each page contains a plurality of sectors, and each sector is the minimum unit of data for writing data to or reading data from the flash memory device.

In some embodiments, storage controller 124 includes a management module 121-1, a host interface 129, an input buffer 123-1, an output buffer 123-2, an error control module 125 and a storage medium I/O interface 128. Storage controller 124 may include various additional features that have not been illustrated for the sake of brevity and so as not to obscure pertinent features of the example embodiments disclosed herein, and a different arrangement of features may be possible. Host interface 129 provides an interface to computer system 110 through data connections 101. Similarly, storage medium I/O 128 provides an interface to storage medium 130 though connections 103. In some embodiments, storage medium I/O 128 includes read and write circuitry, including circuitry capable of providing reading signals to storage medium 130 (e.g., reading threshold voltages for NAND-type flash memory).

In some embodiments, management module 121-1 includes one or more processing units 122-1 (sometimes herein called CPUs, processors, or hardware processors, and sometimes implemented using microprocessors, microcontrollers, or the like) configured to execute instructions in one or more programs (e.g., in management module 121-1). In some embodiments, the one or more CPUs 122-1 are shared by one or more components within, and in some cases, beyond the function of storage controller 124. Management module 121-1 is coupled to host interface 129, error control module 125 and storage medium I/O 128 in order to coordinate the operation of these components. In some embodiments, one or more modules of management module 121-1 are implemented in management module 121-2 of computer system 110. In some embodiments, one or more processors of computer system 110 (not shown) are configured to execute instructions in one or more programs (e.g., in management module 121-2). Management module 121-2 is coupled to storage device 120 in order to manage the operation of storage device 120.

Error control module 125 is coupled to storage medium I/O 128, input buffer 123-1, output buffer 123-2, and management module 121-1. Error control module 125 is provided to limit the number of uncorrectable errors inadvertently introduced into data during writes to memory or reads from memory. In some embodiments, error control module 125 is executed in software by the one or more CPUs 122-1 of management module 121-1, and, in other embodiments, error control module 125 is implemented in whole or in part using special purpose circuitry to perform data encoding and decoding functions. To that end, error control module 125 includes an encoder 126 and a decoder 127. Encoder 126 encodes data by applying an error control code to produce a codeword, which is subsequently stored in storage medium 130.

When the encoded data (e.g., one or more codewords) is read from storage medium 130, decoder 127 applies a decoding process to the encoded data to recover the data, and to correct errors in the recovered data within the error correcting capability of the error control code. Those skilled in the art will appreciate that various error control codes have different error detection and correction capacities, and that particular codes are selected for various applications for reasons beyond the scope of this disclosure. As such, an exhaustive review of the various types of error control codes is not provided herein. Moreover, those skilled in the art will appreciate that each type or family of error control codes may have encoding and decoding algorithms that are particular to the type or family of error control codes. On the other hand, some algorithms may be utilized at least to some extent in the decoding of a number of different types or families of error control codes. As such, for the sake of brevity, an exhaustive description of the various types of encoding and decoding algorithms generally available and known to those skilled in the art is not provided herein.

During a write operation, input buffer 123-1 receives data to be stored in storage medium 130 from computer system 110. The data held in input buffer 123-1 is made available to encoder 126, which encodes the data to produce one or more codewords. The one or more codewords are made available to storage medium I/O 128, which transfers the one or more codewords to storage medium 130 in a manner dependent on the type of storage medium being utilized.

A read operation is initiated when computer system (host) 110 sends one or more host read commands (e.g., via data connections 101) to storage controller 124 requesting data from storage medium 130. Storage controller 124 sends one or more read access commands to storage medium 130, via storage medium I/O 128, to obtain raw read data in accordance with memory locations (addresses) specified by the one or more host read commands. Storage medium I/O 128 provides the raw read data (e.g., comprising one or more codewords) to decoder 127. If the decoding is successful, the decoded data is provided to output buffer 123-2, where the decoded data is made available to computer system 110. In some embodiments, if the decoding is not successful, storage controller 124 may resort to a number of remedial actions or provide an indication of an irresolvable error condition.

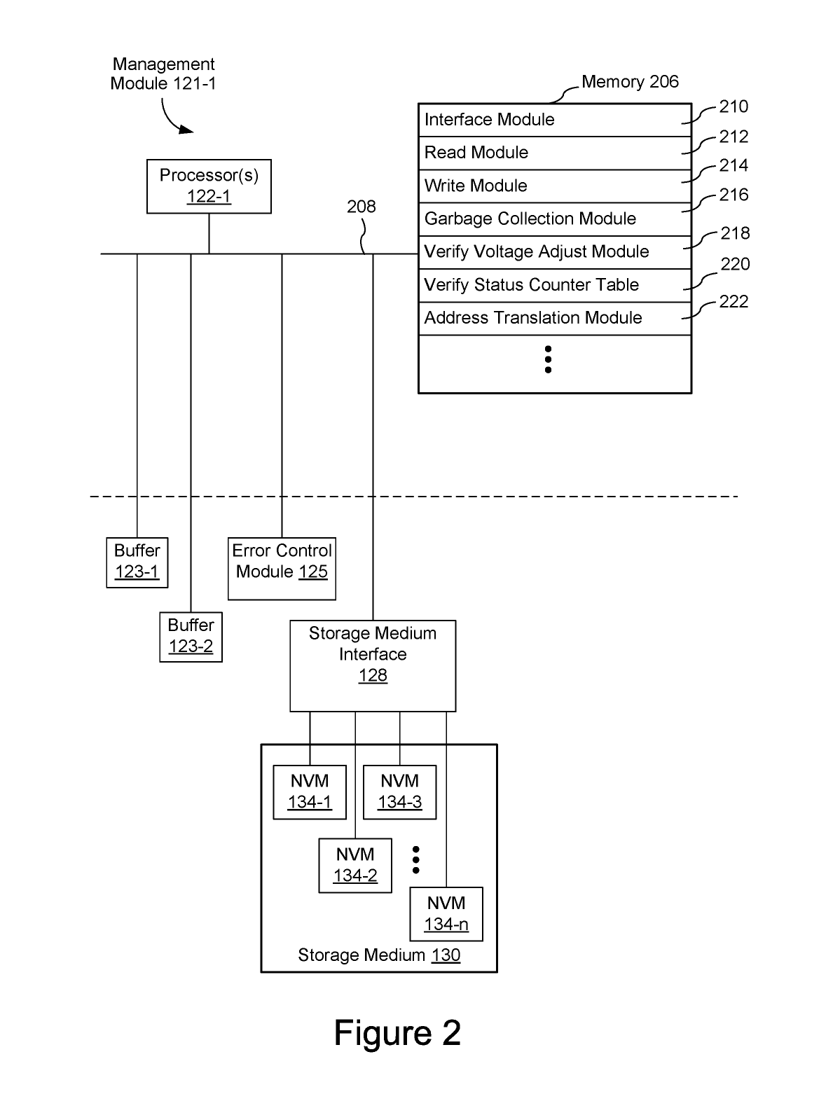

FIG. 2 is a block diagram illustrating an implementation of a management module 121-1 (hereinafter management module 121 unless specifically designated otherwise), in accordance with some embodiments. Management module 121 typically includes one or more processing units 122-1 (sometimes herein called CPUs, processors, or hardware processors, and sometimes implemented using microprocessors, microcontrollers, or the like) for executing modules, programs and/or instructions stored in memory 206 and thereby performing processing operations; memory 206 (sometimes herein called controller memory); and one or more communication buses 208 for interconnecting these components. Communication buses 208 optionally include circuitry (sometimes called a chipset) that interconnects and controls communications between system components. In some embodiments, management module 121 is coupled to buffers 123-1 and 123-2, error control module 125, and storage medium I/O 128 by communication buses 208. Memory 206 includes high-speed random access memory, such as DRAM, SRAM, DDR RAM or other random access solid state memory devices, and may include non-volatile memory, such as one or more magnetic disk storage devices, optical disk storage devices, flash memory devices, or other non-volatile solid state storage devices. Memory 206 optionally includes one or more storage devices remotely located from processor(s) 122-1. Memory 206, or alternately the non-volatile memory device(s) within memory 206, comprises a non-transitory computer readable storage medium. In some embodiments, memory 206, or the computer readable storage medium of memory 206 stores the following programs, modules, and data structures, or a subset or superset thereof:
an interface module 210 used for communicating with other components, such as non-volatile memory devices 134, and computer system 110;
a read module 212 used for reading from non-volatile memory devices 134;
a write module 214 used for writing to non-volatile memory devices 134;
a garbage collection module 216 used for controlling a garbage collection process in a storage medium (e.g., storage medium 130, FIG. 1);
a verify voltage adjust module 218 used for adjusting a verify voltage used to verify data written to non-volatile memory devices 134;
a verify status table 220 that stores information associated with verify trigger events;
an address translation module 222 that is used for mapping logical addresses to physical addresses.

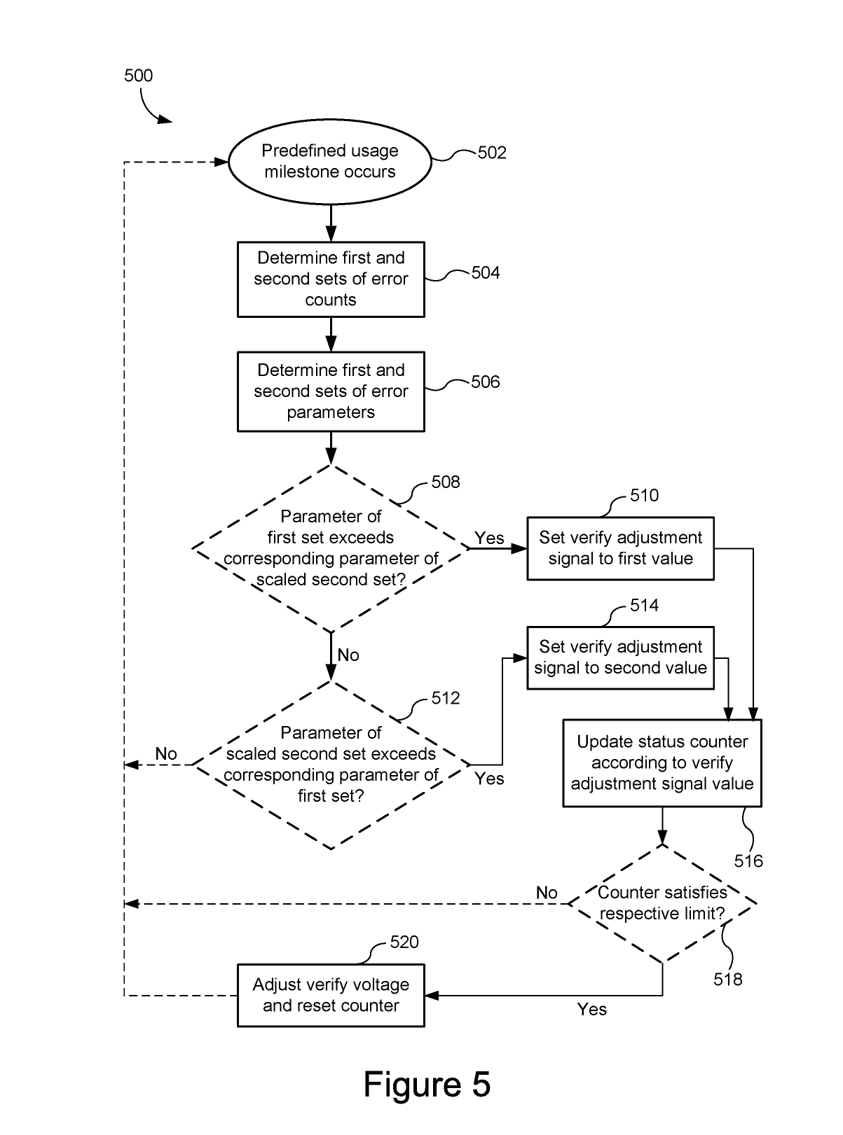

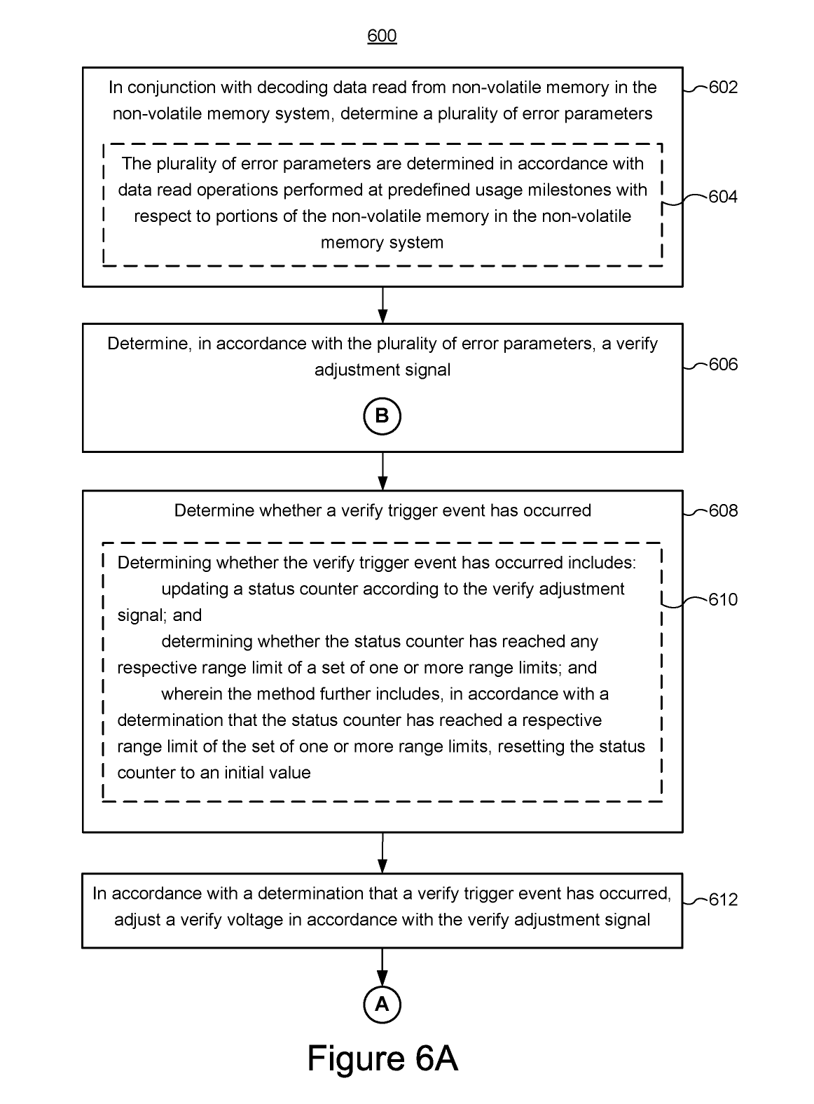

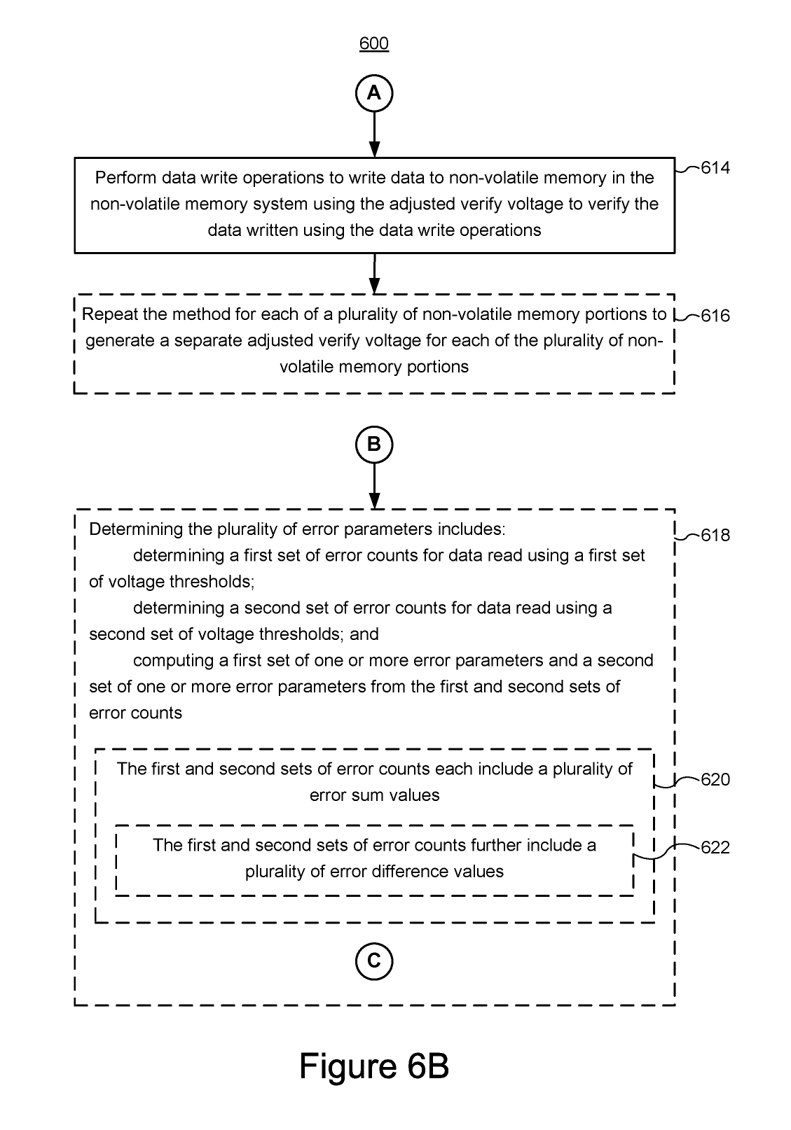

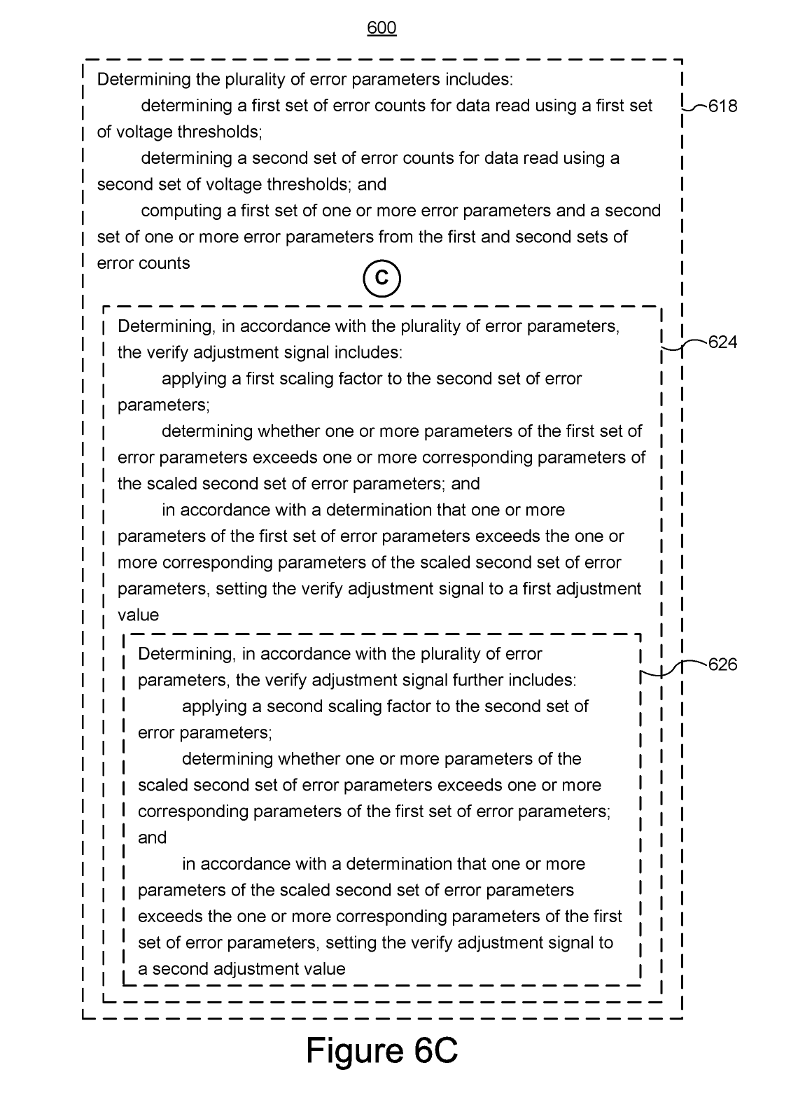

Each of the above identified elements may be stored in one or more of the previously mentioned memory devices that together form memory 206, and corresponds to a set of instructions for performing a function described above. The above identified modules or programs (i.e., sets of instructions) need not be implemented as separate software programs, procedures or modules, and thus various subsets of these modules may be combined or otherwise re-arranged in various embodiments. In some embodiments, memory 206 may store a subset of the modules and data structures identified above. Furthermore, memory 206 may store additional modules and data structures not described above. In some embodiments, the programs, modules, and data structures stored in memory 206, or the computer readable storage medium of memory 206, provide instructions for implementing respective operations in the methods described below with reference to FIGS. 5 and 6A-6C.

Although FIG. 2 shows management module 121-1, FIG. 2 is intended more as a functional description of the various features which may be present in a management module, or non-volatile memory controller, than as a structural schematic of the embodiments described herein. In practice, and as recognized by those of ordinary skill in the art, items shown separately could be combined and some items could be separated. Further, as noted above, in some embodiments, one or more modules of management module 121-1 are implemented in management module 121-2 of computer system 110.

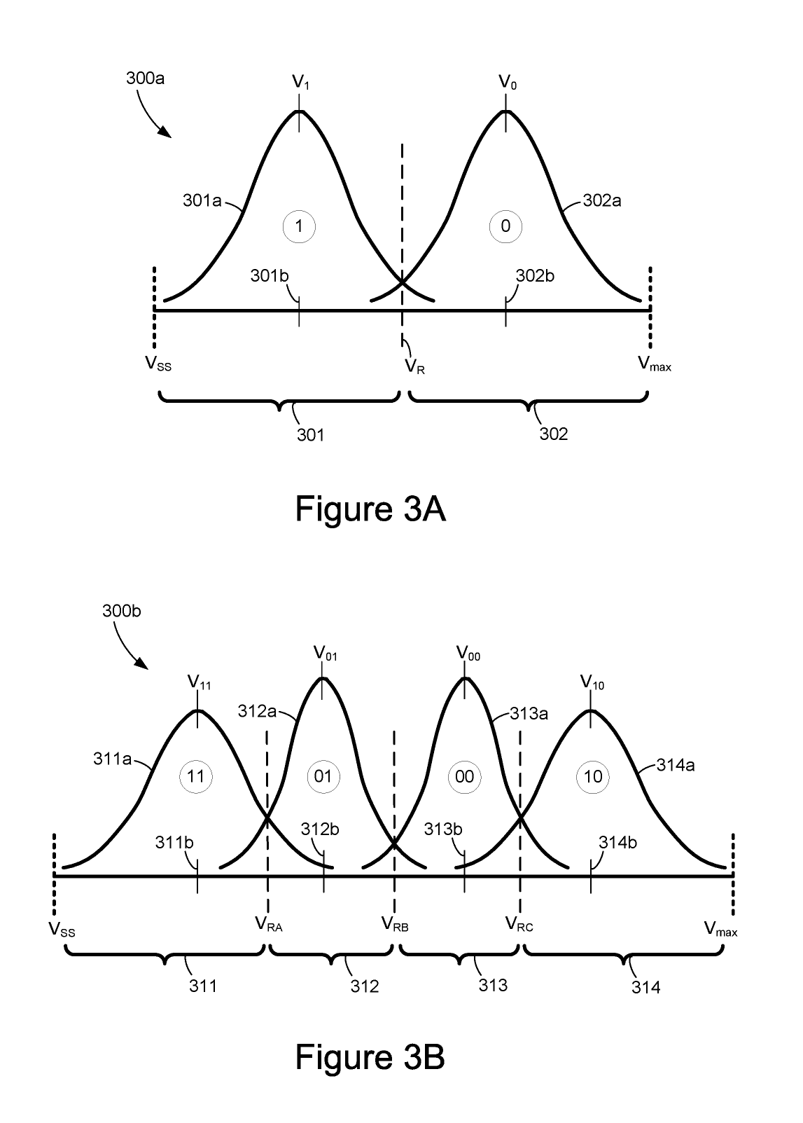

As discussed below with reference to FIG. 3A, a single-level flash memory cell (SLC) stores one bit (“0” or “1”). Thus, the storage density of an SLC memory device is one bit of information per memory cell. A multi-level flash memory cell (MLC), however, can store two or more bits of information per cell by using different ranges within the total voltage range of the memory cell to represent a multi-bit bit-tuple. In turn, the storage density of an MLC memory device is multiple-bits per cell (e.g., two bits per memory cell).

Flash memory devices utilize memory cells to store data as electrical values, such as electrical charges or voltages. Each flash memory cell typically includes a single transistor with a floating gate that is used to store a charge, which modifies the threshold voltage of the transistor (i.e., the voltage needed to turn the transistor on). The magnitude of the charge, and the corresponding threshold voltage, is used to represent one or more data values. In some embodiments, during a read operation, a reading threshold voltage is applied to the control gate of the transistor and the resulting sensed current or voltage is mapped to a data value.

The terms “cell voltage” and “memory cell voltage,” in the context of flash memory cells, typically mean the threshold voltage of the memory cell, which is the minimum voltage that needs to be applied to the gate of the memory cell's transistor in order for the transistor to conduct current. Similarly, reading threshold voltages (sometimes also called reading signals, reading voltages, and/or read thresholds) applied to flash memory cells are gate voltages applied to the gates of the flash memory cells to determine whether the memory cells conduct current at that gate voltage. In some embodiments, when a flash memory cell's transistor conducts current at a given reading threshold voltage, indicating that the cell voltage is less than the reading threshold voltage, the raw data value for that read operation is a “1,” and otherwise the raw data value is a “0.”

FIG. 3A is a simplified, prophetic diagram of voltage distributions 300a found in a set of single-level flash memory cells (SLC) over time, in accordance with some embodiments. The voltage distributions 300a shown in FIG. 3A have been simplified for illustrative purposes. In this example, the SLC's cell voltage range extends approximately from a first voltage, V_{SS} (e.g., 0 volts), to a maximum allowed gate voltage, Vₘₐₓ (e.g., 6 volts). As such, voltage distributions 300a extend between V_{SS} and Vₘₐₓ. In some embodiments, the voltage distributions 300a may represent a histogram of cell voltages corresponding to SLC memory cells in a respective portion (e.g., a page, word line or block) of flash memory.

Sequential voltage ranges 301 and 302 between voltages V_{SS} and Vₘₐₓ are used to represent corresponding bit values “1” and “0,” respectively. Each voltage range 301, 302 has a respective center voltage V₁ 301b, V₀ 302b. As described below, in many circumstances the memory cell current sensed in response to an applied reading threshold voltages is indicative of a memory cell voltage different from the respective center voltage V₁ 301b or V₀ 302b corresponding to the respective bit value written into the memory cell. Errors in cell voltage, and/or the cell voltage sensed when reading the memory cell, can occur during write operations, read operations, or due to “drift” of the cell voltage between the time data is written to the memory cell and the time a read operation is performed to read the data stored in the memory cell. For ease of discussion, these effects are collectively described as “cell voltage drift.” Each voltage range 301, 302 also has a respective voltage distribution 301a, 302a that may occur as a result of any number of a combination of error-inducing factors, examples of which are identified above.

In some implementations, a reading threshold voltage V_{R} is applied between adjacent center voltages (e.g., applied proximate to the halfway region between adjacent center voltages V₁ 301b and V₀ 302b). Optionally, in some implementations, the reading threshold voltage is located between voltage ranges 301 and 302. In some implementations, reading threshold voltage V_{R} is applied in the region proximate to where the voltage distributions 301a and 302a overlap, which is not necessarily proximate to the halfway region between adjacent center voltages V₁ 301b and V₀ 302b.

In order to increase storage density in flash memory, flash memory has developed from single-level (SLC) cell flash memory to multi-level cell (MLC) flash memory so that two or more bits can be stored by each memory cell. As discussed below with reference to FIG. 3B, an MLC flash memory device is used to store multiple bits by using voltage ranges within the total voltage range of the memory cell to represent different bit-tuples. An MLC flash memory device is typically more error-prone than an SLC flash memory device created using the same manufacturing process because the effective voltage difference between the voltages used to store different data values is smaller for an MLC flash memory device. Moreover, due to any number of a combination of factors, such as electrical fluctuations, defects in the storage medium, operating conditions, device history, and/or write-read circuitry, a typical error includes a stored voltage level in a particular MLC being in a voltage range that is adjacent to the voltage range that would otherwise be representative of the correct storage of a particular bit-tuple. As discussed in greater detail below with reference to FIG. 3B, the impact of such errors can be reduced by gray-coding the data, such that adjacent voltage ranges represent single-bit changes between bit-tuples.

FIG. 3B is a simplified, prophetic diagram of voltage distributions 300b found in a set of multi-level flash memory cells (MLC) over time, in accordance with some embodiments. The voltage distributions 300b shown in FIG. 3B have been simplified for illustrative purposes. In this example, the MLC's cell voltage range extends approximately from a first voltage, V_{SS}, to a maximum allowed gate voltage, Vₘₐₓ. As such, voltage distributions 300b extend between V_{SS} and Vₘₐₓ. In some embodiments, the voltage distributions 300b may represent a histogram of cell voltages corresponding to MLC memory cells in a respective portion (e.g., a page, word line or block) of flash memory.

Sequential voltage ranges 311, 312, 313, 314 between voltages V_{SS} and Vₘₐₓ are used to represent corresponding bit-tuples “11,” “01,” “00,” “10,” respectively. Each voltage range 311, 312, 313, 314 has a respective center voltage 311b, 312b, 313b, 314b. Each voltage range 311, 312, 313, 314 also has a respective voltage distribution 311a, 312a, 313a, 314a that may occur as a result of any number of a combination of factors, such as electrical fluctuations, defects in the storage medium, operating conditions, device history (e.g., number of program-erase (PE) cycles), and/or imperfect performance or design of write-read circuitry.

Ideally, during a write operation, the charge on the floating gate of the MLC would be set such that the resultant cell voltage is at the center of one of the ranges 311, 312, 313, 314 in order to write the corresponding bit-tuple to the MLC. Specifically, the resultant cell voltage would be set to one of V₁₁ 311b, V₀₁ 312b, V₀₀ 313b and V₁₀ 314b in order to write a corresponding one of the bit-tuples “11,” “01,” “00” and “10.” In reality, due to the factors mentioned above, the initial cell voltage may differ from the center voltage for the data written to the MLC.

Reading threshold voltages V_{RA}, V_{RB} and V_{RC} are positioned between adjacent center voltages (e.g., positioned at or near the halfway point between adjacent center voltages) and, thus, define threshold voltages between the voltage ranges 311, 312, 313, 314. Optionally, in some implementations, the reading threshold voltages are located between adjacent voltage ranges 311, 312, 313, 314. In some implementations, reading threshold voltages V_{RA}, V_{RB}, and V_{RC} are applied in the regions proximate to where adjacent voltage distributions 311a, 312a, 313a, 314a overlap, which are not necessarily proximate to the halfway regions between adjacent center voltages V₁₁ 311b, V₀₁ 312b, V₀₀ 313b and V₁₀ 314b. In some implementations, the reading threshold voltages are selected or adjusted to minimize error. During a read operation, one of the reading threshold voltages V_{RA}, V_{RB} and V_{RC} is applied to determine the cell voltage using a comparison process. However, due to the various factors discussed above, the actual cell voltage, and/or the cell voltage received when reading the MLC, may be different from the respective center voltage V₁₁ 311b, V₀₁ 312b, V₀₀ 313b or V₁₀ 314b corresponding to the data value written into the cell. For example, the actual cell voltage may be in an altogether different voltage range, strongly indicating that the MLC is storing a different bit-tuple than was written to the MLC. More commonly, the actual cell voltage may be close to one of the read comparison voltages, making it difficult to determine with certainty which of two adjacent bit-tuples is stored by the MLC.

Errors in cell voltage, and/or the cell voltage received when reading the MLC, can occur during write operations, read operations, or due to “drift” of the cell voltage between the time data is written to the MLC and the time a read operation is performed to read the data stored in the MLC. For ease of discussion, sometimes errors in cell voltage, and/or the cell voltage received when reading the MLC, are collectively called “cell voltage drift.”

One way to reduce the impact of a cell voltage drifting from one voltage range to an adjacent voltage range is to gray-code the bit-tuples. Gray-coding the bit-tuples includes constraining the assignment of bit-tuples such that a respective bit-tuple of a particular voltage range is different from a respective bit-tuple of an adjacent voltage range by only one bit. For example, as shown in FIG. 3B, the corresponding bit-tuples for adjacent ranges 301 and 302 are respectively “11” and “01,” the corresponding bit-tuples for adjacent ranges 302 and 303 are respectively “01” and “00,” and the corresponding bit-tuples for adjacent ranges 303 and 304 are respectively “00” and “10.” Using gray-coding, if the cell voltage drifts close to a read comparison voltage level, the error is typically limited to a single bit within the 2-bit bit-tuple.

Although the description of FIG. 3B uses an example in which q=2 (i.e., 2 bits per cell in an MLC flash memory), those skilled in the art will appreciate that the embodiments described herein may be extended to memory cells that have more than four possible states per cell, yielding more than two bits of information per cell. For example, in some embodiments, a triple-level memory cell (TLC) has eight possible states per cell, yielding three bits of information per cell. As another example, in some embodiments, a quad-level memory cell (QLC) has 16 possible states per cell, yielding four bits of information per cell. As another example, in some embodiments, a cell might store only 6 states, yielding approximately 2.5 bits of information per cell, meaning that two cells together would provide 36 possible states, more than sufficient to store 5 bits of information per pair of cells.

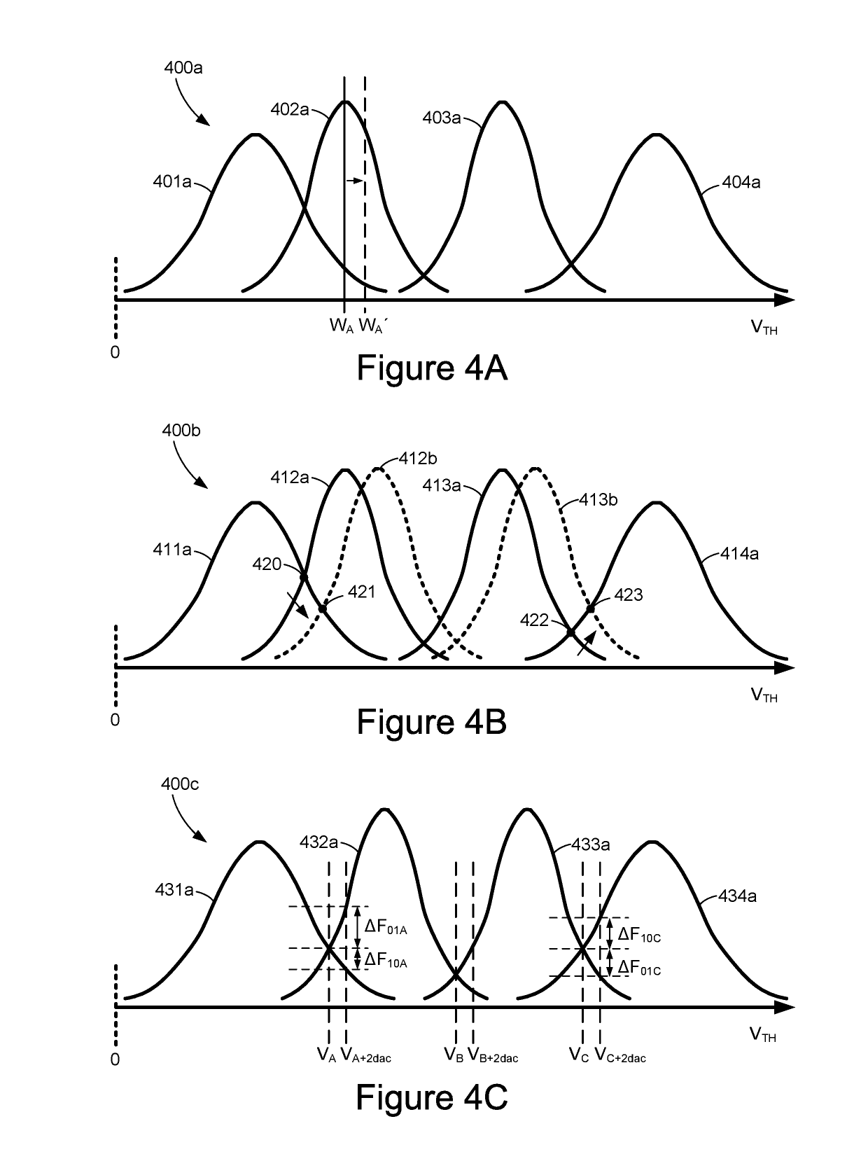

FIG. 4A is a conceptual diagram showing adjustment of a verify voltage W_{A} in a non-volatile memory system, in accordance with some embodiments. The voltage distributions 400a have been simplified for illustrative purposes. Voltage distributions 401a, 402a, 403a, 404a are used to represent distributions (or a histogram) of cell voltages corresponding to MLC memory cells in a respective portion of flash memory in the non-volatile memory system. In other words, voltage distributions 401a, 402a, 403a, 404a are used to represent distributions of cell voltages corresponding to bit-tuples “11,” “01,” “00,” “10,” respectively. In some embodiments, writing data to a memory cell requires verifying that the data was properly written using a verify voltage corresponding to the data value. The verify voltage is sometimes called a write verify voltage, program verify voltage, or write/program verify threshold. In this example, verify voltage W_{A} is used to verify bit-tuple “01.” In some embodiments, however, it is desirable to adjust the verify voltage, as shown in FIG. 4A, such that a different verify voltage W_{A}′ is used to verify bit-tuple “01.”

FIG. 4B is a conceptual diagram of the effect of verify voltage adjustment on voltage distributions 400b that may be found in an MLC over time, in accordance with some embodiments. The voltage distributions 400b have been simplified for illustrative purposes. Voltage distributions 411a, 412a, 413a, 414a are used to represent distributions of cell voltages corresponding to bit-tuples “11,” “01,” “00,” “10,” respectively. In addition, tail portions of voltage distributions 411a, 412a, 413a, 414a represent the incidence of error, or “error rate,” corresponding to bit-tuples “11,” “01,” “00,” “10,” respectively. The tail portions are determined by the read threshold voltages. For example, the tail portion of voltage distribution 411a to the right of a corresponding read threshold voltage (e.g., read threshold voltage V_{RA}, FIG. 3B) represents the error rate corresponding to a data value “11” being written to a memory cell (e.g., as shown by voltage distribution 311a, FIG. 3B) but a data value “01” being sensed from the memory cell. Stated another way, the right tail portion of voltage distribution 411a represents the error rate corresponding to the upper bit (sometimes called the upper page) of data value “11” being written as “1” but sensed as “0” (also referred to as “10 error” or “1 to 0 error”). Conversely, the tail portion of voltage distribution 412a to the left of a corresponding read threshold voltage (e.g., read threshold voltage V_{RA}, FIG. 3B) represents the error rate corresponding to a data value “01” being written to a memory cell (e.g., as shown by voltage distribution 312a, FIG. 3B) but a data value “11” being sensed from the memory cell; in other words, the left tail portion of voltage distribution 412a represents the error rate corresponding to the upper bit of data value “01” being written as “0” but sensed as “1” (also referred to as “01” or “0 to 1” error).

Similarly, the tail portion of voltage distribution 413a to the right of a corresponding read threshold voltage (e.g., read threshold voltage V_{RC}, FIG. 3B) represents the error rate corresponding to a data value “00” being written (e.g., as shown by voltage distribution 313a, FIG. 3B) but a data value “10” being sensed. In other words, the right tail portion of voltage distribution 413a represents the error rate corresponding to the upper bit of data value “00” being written as “0” but sensed as “1” (also referred to as “01” or “0 to 1” error). Likewise, the left tail portion of voltage distribution 414a to the left of a corresponding read threshold voltage (e.g., read threshold voltage V_{RC}, FIG. 3B) represents the error rate corresponding to a data value “10” being written (e.g., as shown by voltage distribution 314a, FIG. 3B) but sensed as “00,” or in other words the upper bit being written as “1” but sensed as “0” (also referred to as “10” or “1 to 0” error).

The voltage distributions 400b corresponding to bit-tuples “11,” “01,” “00,” “10,” respectively, are sometimes referred to as “E,” “A,” “B,” “C” levels or states, respectively. For example, in FIG. 4B, voltage distribution 411a is sometimes referred to as “E,” voltage distribution 412a as “A,” voltage distribution 413a as “B,” and voltage distribution 414a as “C.” The intersection between E 411a and A 412a is sometimes referred to as the E-A distribution crossover 420 (also referred to herein as crossover or crossover point). Similarly, the intersection between B 413a and C 414a is sometimes referred to as the B-C distribution crossover 422. In some embodiments, the overall storage raw bit error rate of a respective portion of non-volatile memory can be improved or optimized by equating the E-A crossover 420 and the B-C crossover 422. Reducing the overall storage raw bit error rate can in turn improve the reliability and endurance of the non-volatile memory. In other embodiments, setting the E-A crossover point to be lower than the B-C crossover point may improve reliability and endurance for non-volatile memory that is used primarily for read operations. Alternatively, in some embodiments, setting the E-A crossover point to be higher than the B-C crossover point may improve reliability and endurance for non-volatile memory that is used primarily for data retention.

In some embodiments, the voltage distributions E, A, B, C are related to verify voltages E-verify, A-verify, B-verify, C-verify, respectively. Adjusting a verify voltage shifts the corresponding voltage distribution accordingly. For example, as shown in FIG. 4B, adjusting the A-verify voltage shifts the A voltage distribution 412a to 412b. In some embodiments, as shown in FIG. 4B, the B voltage distribution is shifted from 413a to 413b in conjunction with adjusting the A voltage distribution 412a to 412b. In some embodiments, the verify voltages (e.g., the A-verify voltage and the B-verify voltage) are adjusted separately. In some embodiments, a verify voltage is adjusted in conjunction with adjustment of another verify voltage based on a feedback loop. In the example shown in FIG. 4B, prior to adjusting the A-verify voltage, the E-A crossover 420 between E 411a and A 412a was higher than the B-C crossover 422 between B 413a and C 414a. Shifting the A voltage distribution 412a lowers the E-A crossover point 420 to 421. Shifting the B voltage distribution 413a raises the B-C crossover point 422 to 423.

FIG. 4C is a conceptual diagram of error parameters derived from an error control module (e.g., error control module 125, FIGS. 1 and 2) in a non-volatile memory system, in accordance with some embodiments. The voltage distributions 400c have been simplified for illustrative purposes. The tail portions of voltage distributions 431a, 432a, 433a, 434a are used to represent errors due to cell voltage drift of corresponding bit-tuples “11,” “01,” “00,” “10,” respectively, or corresponding states E, A, B, C, respectively, as described above with reference to FIG. 4B. Accordingly, the right tail portion of E voltage distribution 431a (sometimes referred to as F_{10A}) represents the “1 to 0” error rate corresponding to the upper bit of data value “11”; the left tail portion of A voltage distribution 432a (sometimes referred to as F_{01A}) represents the “0 to 1” error rate corresponding to the upper bit of data value “01”; the right tail portion of B voltage distribution 433a (sometimes referred to as F_{01C}) represents the “0 to 1” error rate corresponding to the upper bit of data value “00”; and the left tail portion of C voltage distribution 434a (sometimes referred to as F_{10C}) represents the “1 to 0” error rate corresponding to the upper bit of data value “10.” Error parameters F_{10A}, F_{01A}, F_{01C}, and F_{10C} are discussed in more detail below.

In some embodiments, the error control module (e.g., error control module 125, FIGS. 1 and 2) determines default error rates, including “1 to 0” and “0 to 1” error rates, by performing read operations using read threshold voltages V_{A}, V_{B}, V_{C}. In addition, the error control module (e.g., error control module 125, FIGS. 1 and 2) determines additional error rates by performing read operations using read threshold voltages V_{A+2dac}, V_{B} (or V_{B+2dac}), V_{C+2dac}, where 2dac represents two voltage intervals of a digital-to-analog converter (DAC). With respect to the error rates determined at V_{A} and V_{A+2dac}, the difference between the “1 to 0” error at V_{A} and at V_{A+2dac} (corresponding to voltage distribution 431a) is sometimes referred to as ΔF_{10A}. The difference between the “0 to 1” error at V_{A} and at V_{A+2dac} (corresponding to voltage distribution 432a) is sometimes referred to as ΔF_{01A}. Similarly, with respect to the error rates determined at V_{C} and V_{C+2dac}, the difference between the “0 to 1” error at V_{C} and at V_{C+2dac} (corresponding to voltage distribution 433a) is sometimes referred to as ΔF_{01C}. In addition, the difference between the “1 to 0” error at V_{C} and at V_{C+2dac} (corresponding to voltage distribution 434a) is sometimes referred to as ΔF_{10C}.

FIG. 5 illustrates a conceptual flowchart representation of a method 500 of adjusting a verify voltage in a non-volatile memory system 100, in accordance with some embodiments. With reference to the non-volatile memory system 100 pictured in FIG. 1, in some embodiments, the method 500 is performed by a storage device (e.g., storage device 120, FIG. 1) or one or more components of the storage device (e.g., storage controller 124 of storage device 120, FIG. 1). In some embodiments, the method 500 is governed by instructions that are stored in a non-transitory computer readable storage medium and that are executed by one or more processors of a device, such as the one or more processing units (CPUs) 122-1 of management module 121-1 (FIG. 1).

In some embodiments, some of the operations (or alternatively, steps) of method 500 are performed at a host system (e.g., computer system 110) that is operatively coupled with the storage device, and other operations of method 500 are performed at the storage device. In some of these embodiments, method 500 is governed, at least in part, by instructions that are stored in a non-transitory computer readable storage medium and that are executed by one or more processors (e.g., hardware processors) of the host system (the one or more processors of the host system are not shown in FIG. 1).

With reference to FIG. 2, in some embodiments, the operations of method 500 are performed, at least in part, by a read module (e.g., read module 212, FIG. 2), a write module (e.g., write module 214, FIG. 2), an error control module (e.g., error control module 125, FIG. 2), and a verify voltage adjust module (e.g., verify voltage adjust module 218, FIG. 2). For ease of explanation, the following describes method 500 as performed by a storage device (e.g., by storage device 120, FIG. 1).

The method begins, in some embodiments, in accordance with a predefined usage milestone occurring (502) in the storage device (e.g., storage device 120, FIG. 1). In some embodiments, the predefined usage milestone is determined with respect to one or more memory blocks (e.g., selectable portion of storage medium 131, FIG. 1), for each memory block, or for each block in a predefined subset of memory blocks. In some embodiments, the predefined usage milestone is a predefined number of program/erase (P/E) cycles (e.g., after a respective block or other memory portion has been programmed with data), such as any integer multiple of 32 P/E cycles. In other embodiments, the predefined usage milestone is a predefined time period.

After a predefined usage milestone occurs, the storage device (e.g., storage device 120, FIG. 1, or a component thereof such as error control module 125, FIG. 1), determines (504) a first set of error counts and a second set of error counts. In some embodiments, the first and second sets of error counts are determined in accordance with data read operations performed by a read module (e.g., read module 212, FIG. 2) on non-volatile memory (e.g., selectable portion of storage medium 131, FIG. 1). In some embodiments, data decoding results for data read from the non-volatile memory are used to determine the first and second set of error counts. In some embodiments, the first set of error counts is determined using a first set of voltage thresholds. In some embodiments, the second set of error counts is determined using a second set of voltage thresholds.

For example, in one embodiment, the first set of error counts includes both errorₛᵤₘ and error_{diff} values using a first set of voltage thresholds (e.g., with V_{A} and V_{A+2dac}, FIG. 4C), where errorₛᵤₘ is the sum of the “1 to 0” error rates (e.g., F_{10A} and F_{10C}, as discussed above with respect to FIG. 4C) and “0 to 1” error rates (e.g., F_{01A} and F_{01C}, as discussed above with respect to FIG. 4C) at respective voltage thresholds of the first set of voltage thresholds, and where error_{diff} is the difference between the “1 to 0” error rates and “0 to 1” error rates at respective voltage thresholds of the first set of voltage thresholds. In other words, in this example, the first set of error counts includes two subsets, each represented by two equations (1a-1 and 1a-2, and 1b-1 and 1b-2):

Subset 1a:

errorₛᵤₘ=(F_{10A}+F_{01A})+(F_{10C}+F_{01C}) {eq1a-1}

error_{diff}=(F_{10A}−F_{01A})+(F_{10C}−F_{01C}) {eq1a-2}

where the error rates are determined using read voltage thresholds V_{A}, V_{B}, and V_{C}.

Subset 1b:

errorₛᵤₘ′=(F_{10A}′+F_{01A}′)+(F_{10C}+F_{01C}) {eq1b-1}

error_{diff}′=(F_{10A}′−F_{01A}′)+(F_{10C}−F_{01C}) {eq1b-2}

where the error rates are determined using read threshold voltages V_{A+2dac}, V_{B} (or V_{B+2dac}), and V_{C}.

Further, in this example, the second set of error counts similarly includes errorₛᵤₘ and error_{diff} values using a second set of voltage thresholds (e.g., with V_{C} and V_{C+2dac}, FIG. 4C) and similarly includes two subsets. The first subset of the second set of error counts includes the error rates errorₛᵤₘ and error_{diff} determined using read threshold voltages V_{A}, V_{B}, and V_{C} as shown above in equations 1a-1 and 1a-2. The second subset of the second set of error counts includes the error rates determined using read threshold voltages V_{A}, V_{B} (or V_{B+2dac}), and V_{C+2dac}:

Subset 2b:

errorₛᵤₘ″=(F_{10A}+F_{01A})+(F_{10C}′+F_{01C}′) {eq2b-1}

error_{diff}″=(F_{10A}−F_{01A})+(F_{10C}′−F_{01C}′) {eq2b-2}

In some embodiments, the optimal read threshold voltages V_{A}, V_{B}, V_{C} are the voltages at which the total error is at a local minimum. In some embodiments, the optimal read threshold voltages are at the crossover points (e.g., crossover points 420 and 422, FIG. 4B).

Next, the storage device (e.g., storage device 120, FIG. 1, or a component thereof such as verify voltage adjust module 218, FIG. 2) determines (506) a first set of one or more error parameters and a second set of one or more error parameters. In some embodiments, the first and second sets of error parameters are determined in accordance with the first and second sets of error counts. For example, in some embodiments, the first set of error parameters includes ΔF_{10A} and ΔF_{01A} (e.g., as shown in FIG. 4C), and the second set of error parameters includes ΔF_{01C} and ΔF_{10C} (e.g., as shown in FIG. 4C). Referring to the example above, these parameters are determined in accordance with the first and second sets of error counts using at least the steps discussed below. The error parameters ΔF_{10A} and ΔF_{01A} of the first set of error parameters can, in some embodiments, be computed as follows:

$$\begin{matrix}\begin{matrix}{F}_{10} = \frac{{error}_{sum} + {error}_{diff}}{2} \\ = {F}_{10 A} + {F}_{10 C}\end{matrix} & \{ eq 3 a \} \\ \begin{matrix}{F}_{10}^{′} = \frac{{error}_{sum}^{′} + {error}_{diff}^{′}}{2} \\ = {F}_{10 A}^{′} + {F}_{10 C}\end{matrix} & \{ eq 3 b \} \\ \begin{matrix}{F}_{01} = \frac{{error}_{sum} - {error}_{diff}}{2} \\ = {F}_{01 A} + {F}_{01 C}\end{matrix} & \{ eq 3 c \} \\ \begin{matrix}{F}_{01}^{′} = \frac{{error}_{sum}^{′} - {error}_{diff}^{′}}{2} \\ = {F}_{01 A}^{′} + {F}_{01 C}\end{matrix} & \{ eq 3 d \}\end{matrix}$$

where F₁₀, F₁₀′, F₀₁, F₀₁′ are intermediate values used as follows:

ΔF_{10A}=F₁₀′−F₁₀=F₁₀′−F_{10A}, obtained by subtracting equation 3a from equation 3b; and {eq4a}

ΔF_{01A}=F₀₁′−F₀₁=F_{01A}′−F_{01A}, obtained by subtracting equation 3c from equation 3d. {eq4b}

Thus, ΔF_{10A} is the difference between the “1 to 0” error at V_{A} and at V_{A+2dac}, and ΔF_{01A} is the difference between the “0 to 1” error at V_{A} and at V_{A+2dac}, as described above with respect to FIG. 4C.

Similarly, the error parameters ΔF_{01C} and ΔF_{10C} of the second set of error parameters can, in some embodiments, be computed as follows:

$$\begin{matrix}\begin{matrix}{F}_{10}^{″} = \frac{{error}_{sum}^{″} + {error}_{diff}^{″}}{2} \\ = {F}_{10 A} + {F}_{10 C}^{′}\end{matrix} & \{ eq 5 a \} \\ \begin{matrix}{F}_{01}^{″} = \frac{{error}_{sum}^{″} - {error}_{diff}^{″}}{2} \\ = {F}_{01 A} + {F}_{01 C}^{′}\end{matrix} & \{ eq 5 b \}\end{matrix}$$

where F₁₀″ and F₀₁″, in addition to F₁₀ and F₀₁ as determined in equations 3a and 3c, are intermediate values used as follows:

ΔF_{01C}=F₀₁″−F₀₁=F_{01C}′−F_{01C}, obtained by subtracting equation 3c from equation 5b; and {eq6a}

ΔF_{10C}=F₁₀″−F₁₀=F_{10C}′−F_{10C}, obtained by subtracting equation 3a from equation 5a. {eq6b}

Thus, ΔF_{01C} is the difference between the “0 to 1” error at V_{C} and at V_{C+2dac}, and ΔF_{10C} is the difference between the “1 to 0” error at V_{C} and at V_{C+2dac}, as described above with respect to FIG. 4C.

Next, the storage device (e.g., storage device 120, FIG. 1, or a component thereof such as verify voltage adjust module 218, FIG. 2) applies a first scaling factor to the second set of error parameters and determines (508) whether one or more parameters of the first set of error parameters exceed one or more corresponding parameters of the scaled second set of error parameters (to which the first scaling factor has been applied). Alternatively, and mathematically equivalent, the storage device determines whether a ratio of one or more parameters of the first set of error parameters to one or more corresponding parameters of the second set of error parameters exceeds the first scaling factor (which can therefore be considered to be a first threshold). In some embodiments, the first scaling factor is referred to as R₁.

If one or more parameters of the first set of error parameters exceed the one or more corresponding parameters of the R₁-scaled second set of error parameters (or equivalently, the ratio of the one or more parameters of the first set of error parameters to the one or more corresponding parameters of the second set of error parameters exceeds the first scaling factor) (508-Yes), the storage device (e.g., storage device 120, FIG. 1, or a component thereof such as verify voltage adjust module 218, FIG. 2) sets (510) a verify adjustment signal to a first adjustment value. In some embodiments, the verify adjustment signal is referred to as AV_{signal}. Referring to the example above, in some embodiments, the verify adjustment signal is set to the first adjustment value as follows:

If abs(ΔF_{10A})>R₁*abs(ΔF_{01C}) and abs(ΔF_{01A})>R₁*abs(ΔF_{10C}), then AV_{signal}=+1.

where abs(x) represents the absolute value of x.

If one or more parameters of the first set of error parameters do not exceed one or more corresponding parameters of the R₁-scaled second set of error parameters (or equivalently, the aforementioned ratio does not exceed the first scaling factor) (508-No), the storage device (e.g., storage device 120, FIG. 1, or a component thereof such as verify voltage adjust module 218, FIG. 2) applies a second scaling factor to the second set of error parameters and determines (512) whether one or more parameters of the scaled second set of error parameters (to which the second scaling factor has been applied) exceed one or more corresponding parameters of the first set of error parameters. Alternatively, and mathematically equivalent, the storage device determines whether a ratio of one or more parameters of the first set of error parameters to one or more corresponding parameters of the second set of error parameters is less than the second scaling factor (which can therefore be considered to be a second threshold). In some embodiments, the second scaling factor is referred to as R₂. In some embodiments, R₁ and R₂ have distinct values. In some embodiments, R₁ and R₂ have values close to 1. In some embodiments, R₁ is greater than R₂. For example, in some embodiments, R₁ has a value of 1.2 and R₂ has a value of 0.8. In some embodiments, R₁ has a value between 1 and 2, and R₂ has a value between 0.5 and 1. Furthermore, in some embodiments, R₁ and R₂ are determined in accordance with a mathematical relationship. For example, in some embodiments, R₂ is the inverse of R₁.

If one or more parameters of the R₂-scaled second set of error parameters exceed one or more corresponding parameters of the first set of error parameters (or equivalently, the ratio of the one or more parameters of the first set of error parameters to the one or more corresponding parameters of the second set of error parameters is less than the second scaling factor) (512-Yes), the storage device (e.g., storage device 120, FIG. 1, or a component thereof such as verify voltage adjust module 218, FIG. 2) sets (514) the verify adjustment signal to a second adjustment value. Referring to the example above, in some embodiments, the verify adjustment signal AV_{signal} is set to the second adjustment value as follows:

If abs(ΔF_{10A})<R₂*abs(ΔF_{01C}) and abs(ΔF_{01A})<R₂*abs(ΔF_{10C}), then AV_{signal}=−1.

If one or more parameters of the R₂-scaled second set of error parameters do not exceed one or more corresponding parameters of the first set of error parameters (or equivalently, the aforementioned ratio is not less than the second scaling factor) (512-No), the method may repeat (502) in accordance with a subsequent predefined usage milestone.

In some embodiments, if the storage device (e.g., storage device 120, FIG. 1, or a component thereof such as verify voltage adjust module 218, FIG. 2) has set the verify adjustment signal to either the first value (510) or the second value (514), the method proceeds with the storage device updating (516) a status counter (e.g., a status counter in verify status table 220, FIG. 2) according to the value of the verify adjustment signal. In some embodiments, the status counter is referred to as AVₛₜₐₜᵤₛ. Referring to the example above, in some embodiments, the status counter is updated according to the value of the verify adjustment signal as follows:

AVₛₜₐₜᵤₛ=AVₛₜₐₜᵤₛ+AV_{signal}, or equivalently:

If AV_{signal}=+1, then AVₛₜₐₜᵤₛ=AVₛₜₐₜᵤₛ+1;

if AV_{signal}=−1, then AVₛₜₐₜᵤₛ=AVₛₜₐₜᵤₛ−1. {eq7}

While not shown in FIG. 5, in some embodiments, if one or more parameters of the R₂-scaled second set of error parameters do not exceed one or more corresponding parameters of the first set of error parameters (512-No), the method further comprises the storage device setting the verify adjustment signal to a third adjustment value, such as a neutral value (e.g., zero). In these embodiments, the method proceeds with the storage device updating (516) the status counter according to the value of the verify adjustment signal, as discussed above. However, in these embodiments, the neutral value of the verify adjustment signal results in no change to the status counter (516, 518-No). Accordingly, the method may simply repeat (502) in accordance with a subsequent predefined usage milestone.

Next, the storage device (e.g., storage device 120, FIG. 1, or a component thereof such as verify voltage adjust module 218, FIG. 2) determines (518) whether the status counter (e.g., a status counter in verify status table 220, FIG. 2) satisfies a respective range limit of a set of one or more range limits. In some embodiments, the set of one or more range limits includes a maximum limit and a minimum limit. In some embodiments, the maximum limit is a positive limit, and the minimum limit is a negative limit.

If the status counter (e.g., a status counter in verify status table 220, FIG. 2) satisfies a respective limit of the set of one or more range limits (518-Yes), the storage device (e.g., storage device 120, FIG. 1, or a component thereof such as verify voltage adjust module 218, FIG. 2) adjusts (520) a verify voltage in the non-volatile memory system (e.g., non-volatile memory system 100, FIG. 1) and resets the status counter. For example, referring to the example above, if the status counter AVₛₜₐₜᵤₛ satisfies a maximum limit (such as a positive limit), the storage device increases the verify voltage. Conversely, if the status counter AVₛₜₐₜᵤₛ satisfies a minimum limit (such as a negative limit), the storage device decreases the verify voltage. In addition, the storage device resets AVₛₜₐₜᵤₛ to an initial value. In some embodiments, the amount by which the verify voltage is adjusted is a predefined, fixed amount, and furthermore, in some embodiments, the fixed amount by which the verify voltage is increased if the status counter AVₛₜₐₜᵤₛ satisfies the maximum limit is different from the fixed amount by which the verify voltage is decreased if the status counter AVₛₜₐₜᵤₛ satisfies the minimum limit.

If the status counter does not satisfy a respective limit of the set of one or more range limits (518-No), the method may repeat (502) in accordance with a subsequent predefined usage milestone.

In other embodiments, the storage device (e.g., storage device 120, FIG. 1, or a component thereof such as error control module 125, FIG. 1), determines (504) a first of error counts and a second set of error counts including errorₛᵤₘ values but not including error_{diff} values. For example, in one embodiment, the first set of error counts includes errorₛᵤₘ values using a first set of voltage thresholds (e.g., with V_{A} and V_{A+2dac}, FIG. 4C). In other words, in this example, the first set of error counts includes:

errorₛᵤₘ=(F_{10A}+F_{01A})+(F_{10C}+F_{01C}), as determined using read voltage thresholds V_{A}, V_{B}, and V_{C}; and {eq8a}

errorₛᵤₘ′=(F_{10A}′+F_{01A}′)+(F_{10C}+F_{01C}), as determined using read threshold voltages V_{A+2dac}, V_{B} (or V_{B+2dac}), and V_{C}. {eq8b}

Further, in this example, the second set of error counts similarly includes errorₛᵤₘ values using a second set of voltage thresholds (e.g., with V_{C} and V_{C+2dac}, FIG. 4C), including errorₛᵤₘ determined using read threshold voltages V_{A}, V_{B}, and V_{C} as shown above in equation 8a, and further including:

errorₛᵤₘ″=(F_{10A}+F_{01A})+(F_{10C}′+F_{01C}′), as determined using read threshold voltages V_{A}, V_{B} (or V_{B+2dac}), and V_{C+2dac}. {eq9b}

Next, the storage device (e.g., storage device 120, FIG. 1, or a component thereof such as verify voltage adjust module 218, FIG. 2) determines (506) a first set of one or more error parameters and a second set of one or more error parameters. In some embodiments, the first and second sets of error parameters are determined in accordance with the first and second sets of error counts. In some embodiments, the first set of error parameters includes the absolute value of the sum of ΔF_{10A} and ΔF_{01A} (e.g., as shown in FIG. 4C) or abs(ΔF_{10A}+ΔF_{01A}), and the second set of error parameters includes the absolute value of the sum of ΔF_{01C} and ΔF_{10C} (e.g., as shown in FIG. 4C), or abs(ΔF_{01C}+ΔF_{10C}). Referring to the example above, these parameters are determined in accordance with the first and second sets of error counts, for example:

(ΔF_{10A}+ΔF_{01A})=errorₛᵤₘ′−errorₛᵤₘ=(F_{10A}′−F_{10A})+(F_{01A}′−F_{01A})

(ΔF_{01C}+ΔF_{10C})=errorₛᵤₘ″−errorₛᵤₘ=(F_{01C}′−F_{01C})+(F_{10C}′−F_{10C}).

Next, the storage device (e.g., storage device 120, FIG. 1, or a component thereof such as verify voltage adjust module 218, FIG. 2) applies a first scaling factor to the second set of error parameters and determines (508) whether one or more parameters of the first set of error parameters exceed one or more corresponding parameters of the scaled second set of error parameters (to which the first scaling factor has been applied). Alternatively, and mathematically equivalent, the storage device determines whether a ratio of one or more parameters of the first set of error parameters to one or more corresponding parameters of the second set of error parameters exceeds the first scaling factor (which can therefore be considered to be a first threshold). If so (508-Yes), the storage device sets (510) a verify adjustment signal to a first adjustment value. Referring to the example above, in some embodiments, the verify adjustment signal is set to the first adjustment value as follows:

If abs(ΔF_{10A}+ΔF_{01A})>R₁*abs(ΔF_{01C}+ΔF_{10C}), then AV_{signal}=+1.

If not (508-No), the storage device (e.g., storage device 120, FIG. 1, or a component thereof such as verify voltage adjust module 218, FIG. 2) applies a second scaling factor to the second set of error parameters and determines (512) whether one or more parameters of the scaled second set of error parameters (to which the second scaling factor has been applied) exceed one or more corresponding parameters of the first set of error parameters. Alternatively, and mathematically equivalent, the storage device determines whether a ratio of one or more parameters of the first set of error parameters to one or more corresponding parameters of the second set of error parameters is less than the second scaling factor (which can therefore be considered to be a second threshold). If so (512-Yes), the storage device sets (514) the verify adjustment signal to a second adjustment value. Referring to the example above, in some embodiments, the verify adjustment signal is set to the second adjustment value as follows:

If abs(ΔF_{10A}+ΔF_{01A})<R₂*abs(ΔF_{01C}+ΔF_{10C}), then AV_{signal}=−1.

If not (512-No), the method may repeat (502) in accordance with a subsequent predefined usage milestone.

If the storage device (e.g., storage device 120, FIG. 1, or a component thereof such as verify voltage adjust module 218, FIG. 2) has set the verify adjustment signal to either the first value (510) or the second value (514) (or, in some embodiments, a third value such as zero, as discussed above), the method proceeds (516) as discussed previously.

Additional details concerning each of the processing steps for method 500, as well as details concerning additional processing steps, are presented below with reference to FIGS. 6A-6C.

FIGS. 6A-6C illustrate a flowchart representation of a method of adjusting a verify voltage in a non-volatile memory system, in accordance with some embodiments. With reference to the non-volatile memory system 100 pictured in FIG. 1, in some embodiments, a method 600 is performed by a storage device (e.g., storage device 120) or one or more components of the storage device (e.g., storage controller 124). In some embodiments, the method 600 is governed by instructions that are stored in a non-transitory computer-readable storage medium (e.g., controller memory 206, FIG. 2) and that are executed by one or more processors of a device, such as the one or more processing units (CPUs) 122-1 of management module 121-1. In some embodiments, some of the operations of method 600 are performed at a host system (e.g., computer system 110) that is operatively coupled with the storage device, and other operations of method 600 are performed at the storage device. In some embodiments, method 600 is governed, at least in part, by instructions that are stored in a non-transitory computer-readable storage medium and that are executed by one or more processors of the host system (the one or more processors of the host system are not shown in FIG. 1).

With reference to FIG. 2, in some embodiments, the operations of method 600 are performed, at least in part, by a read module (e.g., read module 212, FIG. 2), a write module (e.g., write module 214, FIG. 2), an error control module (e.g., error control module 125, FIG. 2), and a verify voltage adjust module (e.g., verify voltage adjust module 218, FIG. 2). For ease of explanation, the following describes method 600 as performed by a storage device (e.g., by storage device 120, FIG. 1).

With reference to FIG. 6A, the storage device (e.g., storage device 120, FIG. 1, or a component thereof such as verify voltage adjust module 218, FIG. 2), in conjunction with decoding data read from non-volatile memory (e.g., selectable portion 131 of storage device 120, FIG. 1) in the non-volatile memory system (e.g., non-volatile memory system 100, FIG. 1), determines (602) a plurality of error parameters. In some embodiments, the storage device determines the plurality of error parameters as explained above with reference to operations 504 and 506 of method 500.

In some embodiments, the plurality of error parameters are determined (604) in accordance with data read operations performed at predefined usage milestones with respect to portions of the non-volatile memory (e.g., selectable portion 131 of storage device 120, FIG. 1) in the non-volatile memory system (e.g., non-volatile memory system 100, FIG. 1), as explained above with reference to operation 502 of FIG. 5.

The storage device (e.g., storage device 120, FIG. 1, or a component thereof such as verify voltage adjust module 218, FIG. 2) determines (606), in accordance with the plurality of error parameters, a verify adjustment signal. In some embodiments, the verify adjustment signal is determined as explained above with reference to operations 510 and 514 of FIG. 5.

The storage device (e.g., storage device 120, FIG. 1, or a component thereof such as verify voltage adjust module 218, FIG. 2) determines (608) whether a verify trigger event has occurred. In some embodiments, whether a verify trigger event has occurred is determined as explained above with reference to operations 516 and 518 of FIG. 5.

In some embodiments, determining whether the verify trigger event has occurred includes: (1) updating (610) a status counter (e.g., a status counter in verify status table 220, FIG. 2) according to the verify adjustment signal, and (2) determining whether the status counter satisfies any respective range limit of a set of one or more range limits, as explained above with reference to operations 516 and 518 of FIG. 5.

The storage device (e.g., storage device 120, FIG. 1, or a component thereof such as verify voltage adjust module 218, FIG. 2), in accordance with a determination that a verify trigger event has occurred, adjusts (612) a verify voltage in accordance with the verify adjustment signal (e.g., adjusting verify voltage W_{A} to W_{A}′, as shown in FIG. 4A). In some embodiments, the verify voltage is adjusted in accordance with the verify adjustment signal as explained above with reference to operation 520 of FIG. 5. Further, in some embodiments, the storage device (e.g., storage device 120, FIG. 1, or a component thereof such as verify voltage adjust module 218, FIG. 2), in accordance with a determination that the status counter satisfies a respective range limit of the set of one or more range limits, resets (610) the status counter to an initial value, as explained above with reference to operation 520 of FIG. 5.

After the verify voltage has been adjusted (612), the storage device (e.g., storage device 120, FIG. 1, or a component thereof such as write module 214, FIG. 2) performs (614) data write operations to write data to non-volatile memory (e.g., selectable portion 131 of storage device 120, FIG. 1) in the non-volatile memory system (e.g., non-volatile memory system 100, FIG. 1) using the adjusted verify voltage to verify the data written using the data write operations. In some embodiments, performing data write operations using the adjusted verify voltage to verify the data written results in a shift in the voltage distributions of cell voltages in the non-volatile memory (e.g., shifting voltage distribution 412a to 412b and/or shifting voltage distribution 413a to 413b, as shown in FIG. 4B).

In some embodiments, the storage device (e.g., storage device 120, FIG. 1) repeats (616) the method for each of a plurality of non-volatile memory portions (e.g., a plurality of selectable portions 131 of storage device 120, FIG. 1) to generate a separate adjusted verify voltage for each of the plurality of non-volatile memory portions. In some embodiments, a non-volatile memory portion is a page, word line, block or die. In some embodiments, each of the plurality of non-volatile memory portions corresponds to a separate status counter. In some embodiments, one or more status counters corresponding to the plurality of non-volatile memory portions are included in a verify status table (e.g., verify status table 220, FIG. 2). In some embodiments, the status counters are not necessarily stored in a verify status table, and instead a respective status counter corresponding to a respective non-volatile memory portion is stored in a location associated with the corresponding non-volatile memory portion.

In some embodiments, determining the plurality of error parameters includes: (1) determining (618) a first set of error counts for data read using a first set of voltage thresholds, (2) determining a second set of error counts for data read using a second set of voltage thresholds, and (3) computing a first set of one or more error parameters and a second set of one or more error parameters from the first and second sets of error counts, as explained above with reference to operations 504 and 506 of FIG. 5.

In some embodiments, the first and second sets of error counts each include (620) a plurality of error sum values, as explained above with reference to operation 504 of FIG. 5.

In some embodiments, the first and second sets of error counts further include (622) a plurality of error difference values, as explained above with reference to operation 504 of FIG. 5.

In some embodiments, determining, in accordance with the plurality of error parameters, the verify adjustment signal includes: (1) applying (624) a first scaling factor to the second set of error parameters, (2) determining whether one or more parameters of the first set of error parameters exceeds one or more corresponding parameters of the scaled second set of error parameters, and (3) in accordance with a determination that the one or more parameters of the first set of error parameters exceeds the one or more corresponding parameters of the scaled second set of error parameters, setting the verify adjustment signal to a first adjustment value, as explained above with reference to operations 508 and 510 of FIG. 5.

In some embodiments, determining, in accordance with the plurality of error parameters, the verify adjustment signal further includes: (1) applying (626) a second scaling factor to the second set of error parameters, (2) determining whether one or more parameters of the scaled second set of error parameters exceeds one or more corresponding parameters of the first set of error parameters, and (3) in accordance with a determination that the one or more parameters of the scaled second set of error parameters exceeds the one or more corresponding parameters of the first set of error parameters, setting the verify adjustment signal to a second adjustment value, as explained above with reference to operations 512 and 514 of FIG. 5.

It will be understood that, although the terms “first,” “second,” etc. may be used herein to describe various elements, these elements should not be limited by these terms. These terms are only used to distinguish one element from another. For example, a first contact could be termed a second contact, and, similarly, a second contact could be termed a first contact, which changing the meaning of the description, so long as all occurrences of the “first contact” are renamed consistently and all occurrences of the “second contact” are renamed consistently. The first contact and the second contact are both contacts, but they are not the same contact.

The terminology used herein is for the purpose of describing particular embodiments only and is not intended to be limiting of the claims. As used in the description of the embodiments and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific implementations. However, the illustrative discussions above are not intended to be exhaustive or to limit the claims to the precise forms disclosed. Many modifications and variations are possible in view of the above teachings. The implementations were chosen and described in order to best explain principles of operation and practical applications, to thereby enable others skilled in the art.

1. A method of operation in a non-volatile memory system, comprising:
in conjunction with decoding data read from non-volatile memory in the non-volatile memory system, determining a plurality of error parameters;
determining, in accordance with the plurality of error parameters, a verify adjustment signal;
determining whether a verify trigger event has occurred, including:
updating a status counter according to the verify adjustment signal;
in accordance with a determination that a verify trigger event has occurred, adjusting a verify voltage in accordance with the verify adjustment signal, wherein the adjusting includes increasing the verify voltage in accordance with a determination that the status counter satisfies a first limit and decreasing the verify voltage in accordance with a determination that the status counter satisfies a second limit distinct from the first limit; and
performing data write operations to write data to non-volatile memory in the non-volatile memory system using the adjusted verify voltage to verify the data written using the data write operations.

2. The method of claim 1, wherein the plurality of error parameters are determined in accordance with data read operations performed at predefined usage milestones with respect to portions of the non-volatile memory in the non-volatile memory system.

3. The method of claim 1, wherein determining the plurality of error parameters comprises:
determining a first set of error counts for data read using a first set of voltage thresholds;
determining a second set of error counts for data read using a second set of voltage thresholds; and
computing a first set of one or more error parameters and a second set of one or more error parameters from the first and second sets of error counts.

4. The method of claim 3, wherein the first and second sets of error counts each include a plurality of error sum values.

5. The method of claim 4, wherein the first and second sets of error counts further include a plurality of error difference values.

6. The method of claim 3, wherein determining, in accordance with the plurality of error parameters, the verify adjustment signal comprises:
applying a first scaling factor to the second set of error parameters;
determining whether one or more parameters of the first set of error parameters exceeds one or more corresponding parameters of the scaled second set of error parameters; and
in accordance with a determination that the one or more parameters of the first set of error parameters exceeds the one or more corresponding parameters of the scaled second set of error parameters, setting the verify adjustment signal to a first adjustment value.

7. The method of claim 6, wherein determining, in accordance with the plurality of error parameters, the verify adjustment signal further comprises:
applying a second scaling factor to the second set of error parameters;
determining whether one or more parameters of the scaled second set of error parameters exceeds one or more corresponding parameters of the first set of error parameters; and
in accordance with a determination that the one or more parameters of the scaled second set of error parameters exceeds the one or more corresponding parameters of the first set of error parameters, setting the verify adjustment signal to a second adjustment value.

8. The method of claim 1, wherein:
the plurality of error parameters are determined with respect to at least a first voltage threshold and a second voltage threshold; and
the verify adjustment signal is determined in accordance with a ratio of one or more first error rates associated with the first voltage threshold relative to one or more second error rates associated with the second voltage threshold.

9. The method of claim 1, further comprising repeating the method for each of a plurality of non-volatile memory portions to generate a separate adjusted verify voltage for each of the plurality of non-volatile memory portions.

10. A non-volatile memory system, comprising:
non-volatile memory;
one or more processors; and
memory storing one or more programs, which when executed by the one or more processors cause the non-volatile memory system to:
in conjunction with decoding data read from non-volatile memory in the non-volatile memory system, determine a plurality of error parameters;
determine, in accordance with the plurality of error parameters, a verify adjustment signal;
determine whether a verify trigger event has occurred, including:
updating a status counter according to the verify adjustment signal;
in accordance with a determination that a verify trigger event has occurred, adjust a verify voltage in accordance with the verify adjustment signal, wherein the adjusting includes increasing the verify voltage in accordance with a determination that the status counter satisfies a first limit and decreasing the verify voltage in accordance with a determination that the status counter satisfies a second limit distinct from the first limit; and
perform data write operations to write data to non-volatile memory in the non-volatile memory system using the adjusted verify voltage to verify the data written using the data write operations.

11. The non-volatile memory system of claim 10, wherein the one or more processors comprise one or more processors of a storage controller and the one or more programs include a verify voltage adjust module that determines the plurality of error parameters, determines the verify adjustment signal, determines whether the verify trigger event has occurred, and in accordance with a determination that a verify trigger event has occurred, adjusts the verify voltage in accordance with the verify adjustment signal.

12. The non-volatile memory system of claim 10, wherein the plurality of error parameters are determined in accordance with data read operations performed at predefined usage milestones with respect to portions of the non-volatile memory in the non-volatile memory system.

13. The non-volatile memory system of claim 12, wherein the one or more programs include instructions for determining the plurality of error parameters by:
determining a first set of error counts for data read using a first set of voltage thresholds;
determining a second set of error counts for data read using a second set of voltage thresholds; and
computing a first set of one or more error parameters and a second set of one or more error parameters from the first and second sets of error counts.

14. The non-volatile memory system of claim 13, wherein the first and second sets of error counts each include a plurality of error sum values.

15. The non-volatile memory system of claim 14, wherein the first and second sets of error counts further include a plurality of error difference values.

16. The non-volatile memory system of claim 12, wherein the one or more programs include instructions for determining, in accordance with the plurality of error parameters, the verify adjustment signal by:
applying a first scaling factor to the second set of error parameters;
determining whether one or more parameters of the first set of error parameters exceeds one or more corresponding parameters of the scaled second set of error parameters; and
in accordance with a determination that the one or more parameters of the first set of error parameters exceeds the one or more corresponding parameters of the scaled second set of error parameters, setting the verify adjustment signal to a first adjustment value.

17. The non-volatile memory system of claim 16, wherein the one or more programs further include instructions for determining the verify adjustment signal by:
applying a second scaling factor to the second set of error parameters;
determining whether one or more parameters of the scaled second set of error parameters exceeds one or more corresponding parameters of the first set of error parameters; and
in accordance with a determination that the one or more parameters of the scaled second set of error parameters exceeds the one or more corresponding parameters of the first set of error parameters, setting the verify adjustment signal to a second adjustment value.

18. The non-volatile memory system of claim 10, wherein:
the plurality of error parameters are determined with respect to at least a first voltage threshold and a second voltage threshold; and
the verify adjustment signal is determined in accordance with a ratio of one or more first error rates associated with the first voltage threshold relative to one or more second error rates associated with the second voltage threshold.

19. The non-volatile memory system of claim 10, wherein the one or more programs include instructions for generating a separate adjusted verify voltage for each of a plurality of non-volatile memory portions.

20. A non-transitory computer readable storage medium, storing one or more programs configured for execution by one or more processors of a non-volatile memory system, the one or more programs including instructions that when executed by the one or more processors cause the non-volatile memory system to:
in conjunction with decoding data read from non-volatile memory in the non-volatile memory system, determine a plurality of error parameters;
determine whether a verify trigger event has occurred, including:
updating a status counter according to the verify adjustment signal;
in accordance with a determination that a verify trigger event has occurred, adjust a verify voltage in accordance with the verify adjustment signal, wherein the adjusting includes increasing the verify voltage in accordance with a determination that the status counter satisfies a first limit and decreasing the verify voltage in accordance with a determination that the status counter satisfies a second limit distinct from the first limit; and
perform data write operations to write data to non-volatile memory in the non-volatile memory system using the adjusted verify voltage to verify the data written using the data write operations.
